(19) United States
(12) Patent Application Publication
(10) Pub. No.: US 2024/0210832 A1
(43) Pub. Date: Jun. 27, 2024

(54) PHOTORESIST TOPCOAT COMPOSITION, AND METHOD OF FORMING PATTERNS USING THE COMPOSITION

(71) Applicant: Samsung Electronics Co., Ltd., Suwon-si (KR)

(72) Inventors: Chawon KOH, Suwon-si (KR); Sungkun KANG, Suwon-si (KR); Tsunehiro NISHI, Suwon-si (KR); Young Joo CHOI, Suwon-si (KR)

(73) Assignee: Samsung Electronics Co., Ltd., Suwon-si (KR)

(21) Appl. No.: 18/344,992

(22) Filed: Jun. 30, 2023

(30) Foreign Application Priority Data
Dec. 12, 2022 (KR) 10-2022-0173040

(51) Int. Cl. G03F 7/16; G03F 7/004; G03F 7/039; G03F 7/38

(52) U.S. Cl. CPC G03F 7/168; G03F 7/0042; G03F 7/0045; G03F 7/0048; G03F 7/0392; G03F 7/38

(57) ABSTRACT

Disclosed photoresist topcoat compositions including a polymer including at least one of the first structural units represented by Chemical Formula 1 or Chemical Formula 2, a thermal acid generator (TAG), and a solvent; and a method of forming patterns using the photoresist topcoat composition.

### CROSS-REFERENCE TO RELATED APPLICATION

This application claims priority to and the benefit, under 35 U.S.C. § 119, of Korean Patent Application No. 10-2022-0173040 filed in the Korean Intellectual Property Office on Dec. 12, 2022, the entire contents of which are incorporated herein by reference.

### BACKGROUND

### (1) Field

This disclosure relates to photoresist topcoat compositions, methods of forming patterns using photoresist topcoat compositions, photoresist topcoat compositions in which a composition including a polymer including an acid functional group or an acid generating group is applied on or applied to the photoresist layer to form a topcoat, and methods of forming patterns using the same.

### (2) Description of the Related Art

The semiconductor industry has developed ultra-fine techniques having patterns of several to several tens of nanometer size. Such ultrafine techniques may require an effective photolithographic process.

A typical photolithographic process includes providing a material layer on a semiconductor substrate; coating a photoresist layer thereon, exposing and developing the same to provide a photoresist pattern, and etching a material layer using the photoresist pattern as a mask.

As technological development of the photolithographic process increases pattern integration, there may be a demand for materials and technologies for solving various problems accompanied with these advances. In particular, when a photoresist is patterned by using EUV as a light source, and patterns are more refined, EUV light should be more irradiated to a unit area to maintain the same ratio of distribution, this increased exposure dose (mJ/cm²) may contribute to LER (line edge roughness), LWR (line width roughness), LCDU (local CD uniformity), CD (critical dimension) distribution improvement, and defect improvement.

However, a high-NA EUV scanner may be used to increase the exposure dose, which may increase cost.

Accordingly, there may be a demand for developing technology to maintain sensitivity of a PR (photoresist) as well as improve IPU (in-point uniformity) of contact hole (C/H) patterns, LER/LWR of line and space (L/S) patterns, and IPU of pillar patterns to improve a product yield as well as maintain productivity.

### SUMMARY

One aspect of the present disclosure provides a photoresist topcoat composition capable of implementing higher-resolution patterns, improving yield by improving distribution, and/or removing a contact hole not-open defect.

Another aspect of the present disclosure provides methods of forming patterns using the photoresist topcoat composition.

In an example embodiment of the present disclosure, a photoresist topcoat composition may include a polymer including at least one or a combination of the first structural units represented by Chemical Formula 1 or Chemical Formula 2, a thermal acid generator (TAG), and a solvent.

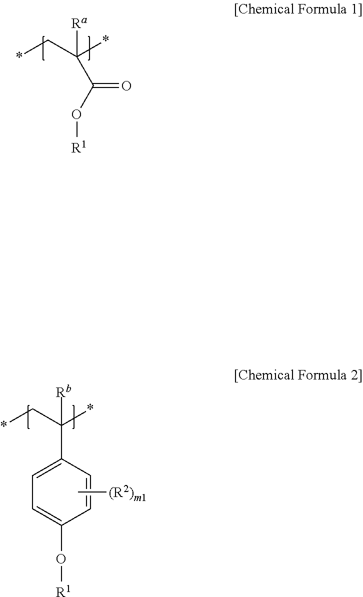

In Chemical Formula 1 and Chemical Formula 2,
R^{a} and R^{b} may each independently be a hydrogen or a methyl group,
R¹ may be an acid functional group or an acid generating group, and
m1 may be an integer from 1 to 4.

R¹ may be a functional group derived from carboxylic acid, sulfonic acid, phosphoric acid, a hydrogen halide, or an L⁸SO₃⁻Q⁺ group,
L⁸ may be a substituted or unsubstituted C1 to C30 alkylene, a substituted or unsubstituted C6 to C30 arylene, or a combination thereof, and
Q⁺ may be an onium cation.

The onium cation may be an ammonium ion, an iodonium ion, a sulfonium ion, or a combination thereof.

An example embodiment of a polymer may further include a second structural unit including at least one fluorine.

An example embodiment of the second structural unit may include at least one or a combination of Chemical Formula 3 to Chemical Formula 5.

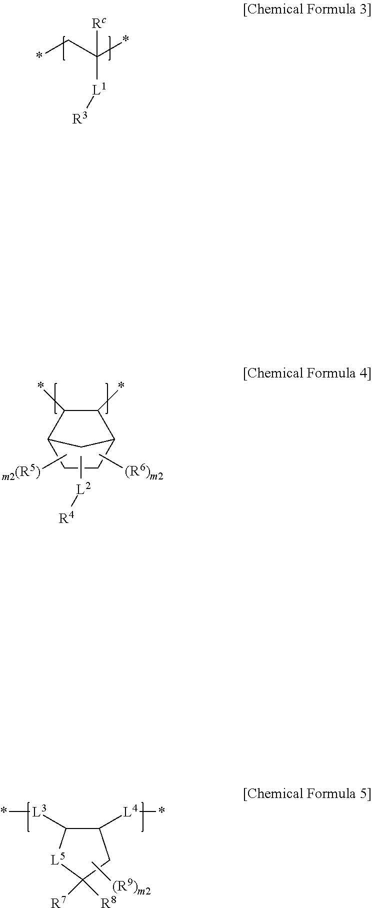

In Chemical Formula 3 to Chemical Formula 5,
R^{c} may be hydrogen or a methyl group,
R⁵ to R⁸ may each independently be hydrogen, a fluoro group, a hydroxy group, a substituted or unsubstituted C1 to C4 alkyl, a substituted or unsubstituted C1 to C4 alkoxy group, or a substituted or unsubstituted C6 to C12 aryl group,
R³, R⁴, and R⁹ may each independently be a substituted or unsubstituted C1 to C30 alkyl group, a substituted or unsubstituted C1 to C30 alkoxy group, or a substituted or unsubstituted C6 to C30 aryl group,
L¹ to L⁶ may each independently be a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a divalent group selected from a substituted or unsubstituted C1 to C30 aliphatic ester, or a combination thereof,
at least one of L¹ and R³ may include a fluoro group,
at least one of L² and R⁴ to R⁶ may include a fluoro group,
at least one of L³ to L⁵ and R⁷ to R⁹ may include a fluoro group, and
m2 is an integer of 1 or 2.

An example embodiment of the second structural unit may include at least one of or a combination of those listed in Group 2.

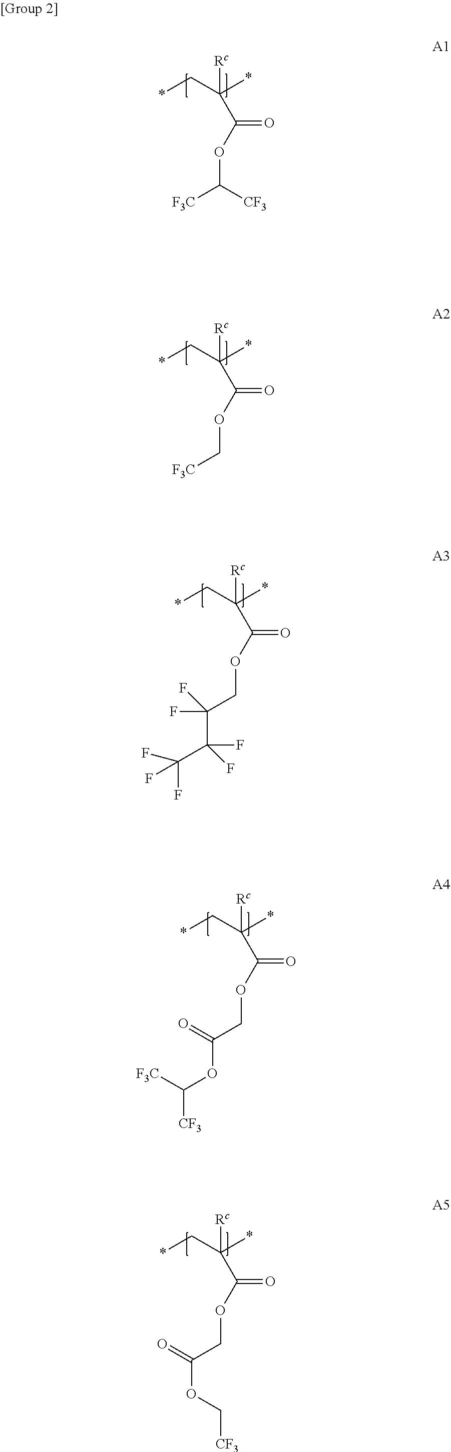

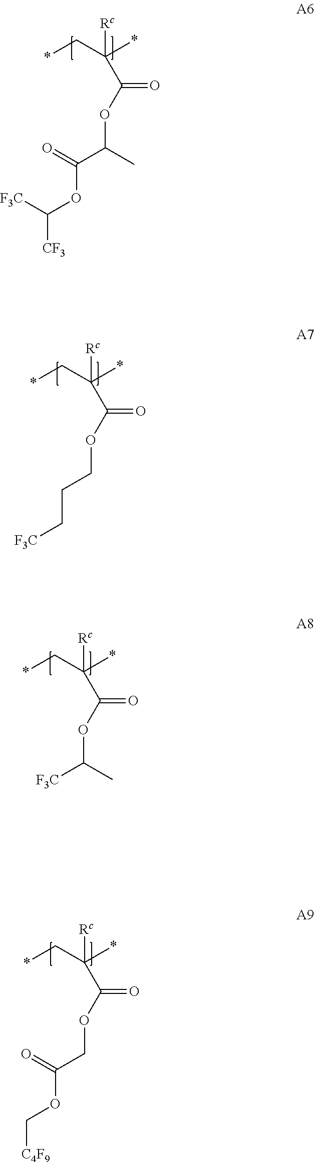

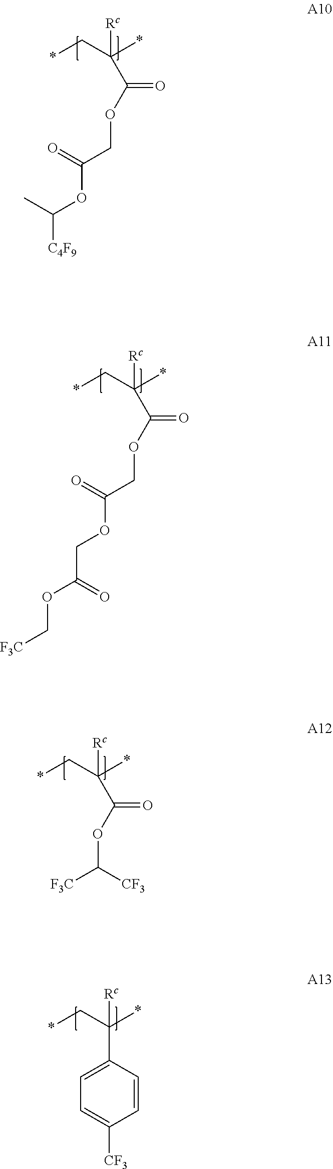

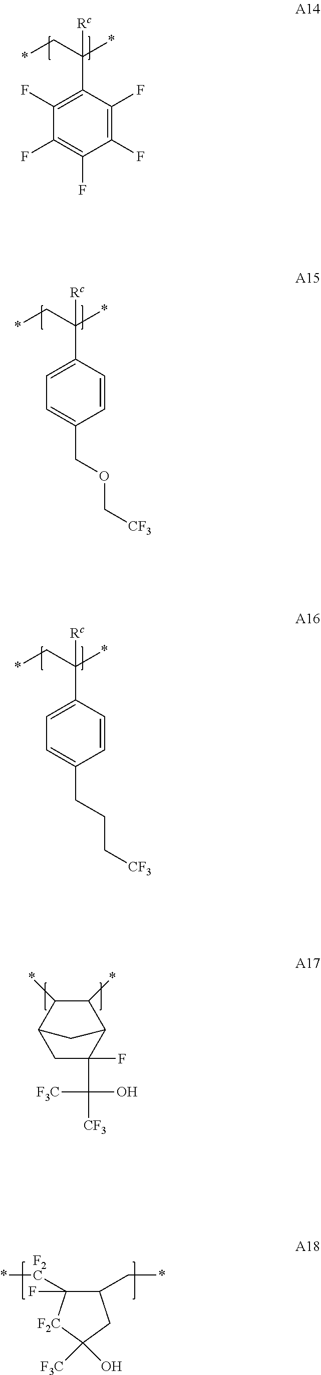

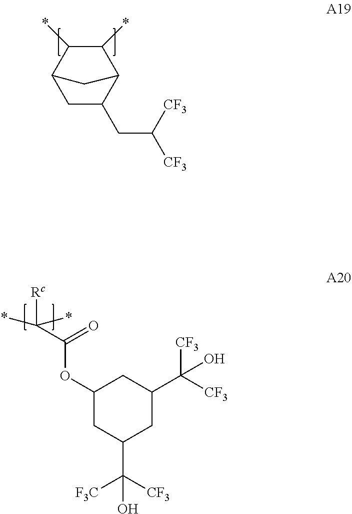

In Group 2,
R^{c} may be hydrogen or a methyl group.

The polymer may further include a third structural unit including at least one element selected from Sn, Sb, Te, I, Ti, Bi, Po, At, In, Hf, Ag, Au, Pt, Si, Al, or Ga.

An example embodiment of the polymer may further include a third structural unit including at least one element selected from Sn, I, In, or Hf.

The third structural unit may be represented by Chemical Formula 6.

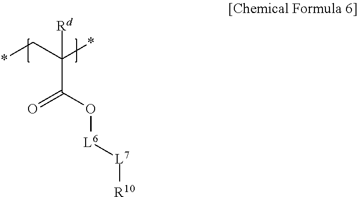

In Chemical Formula 6,
R^{d} may be a hydrogen or a methyl group,
L⁶ and L⁷ may each independently be a divalent group selected from a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a substituted or unsubstituted C1 to C30 aliphatic ester, or a combination thereof,
R¹⁰ may be a substituted or unsubstituted C1 to C30 alkyl group, a substituted or unsubstituted C1 to C30 alkoxy group, or a substituted or unsubstituted C6 to C30 aryl group, and
At least one of L⁶, L⁷, and R¹⁰ may include at least one element selected from Sn, Sb, Te, I, Ti, Bi, Po, At, In, Hf, Ag, Au, Pt, Si, Al, or Ga.

An example embodiment of the third structural unit may include at least one or a combination of those listed in Group 3.

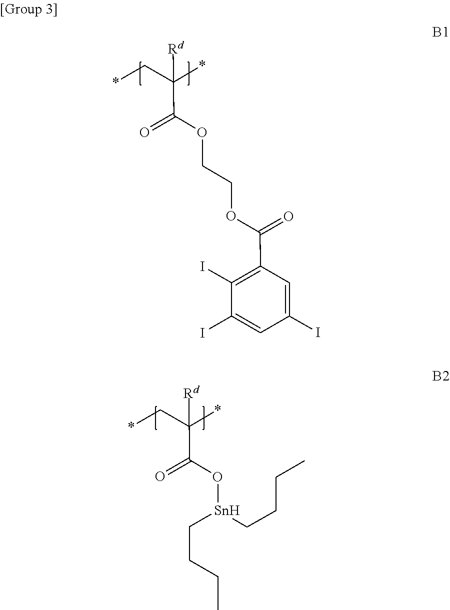

In Group 3,
R^{d} may be a hydrogen or a methyl group.

The thermal acid generator may be at least one of nitrobenzyl tosylate (2-nitrobenzyl tosylate, 3-nitrobenzyl tosylate, 4-nitrobenzyl tosylate, 2,4-dinitrobenzyl tosylate, 2,6-dinitrobenzyl tosylate, or 4-nitrobenzyl tosylate); benzenesulfonate (2-trifluoromethyl-6-nitrobenzyl-4-chlorobenzenesulfonate, 2-trifluoromethyl-6-nitrobenzyl 4-nitrobenzenesulfonate, 2-trifluoromethyl-4-nitrobenzylbenzene sulfonate, 3-trifluoromethyl-4-nitrobenzylbenzene sulfonate); a phenol-based sulfonate ester (phenyl, 4-methoxybenzenesulfonate); an alkyl ammonium salt of an organic acid (a triethylammonium salt of 10-camphorsulfonic acid), trifluoromethylbenzene sulfonic acid, perfluorobutane sulfonic acid; or an onium salt compound.

A weight average molecular weight (Mw) of the polymer may be about 10,000 to about 100,000.

The thermal acid generator may be included in an amount of about 1 wt % to about 30 wt % based on the total solid content of the composition.

The thermal acid generator may be included in an amount of about 10 wt % to about 30 wt % based on the total solid content of the composition.

An example embodiment of an organic solvent may be at least one of MIBC (methyl isobutyl carbinol), ether, PGMEA (propylene glycol monomethyl ether acetate), PGME (propylene glycol monomethyl ether), EL (ethyl lactate), HBM (β-hydroxy β-methylbutyric acid), water, and 2-heptanone.

Another example embodiment of the present disclosure provides methods of forming patterns including applying a photoresist composition on a substrate and performing a soft baking process to form a photoresist layer, applying the aforementioned photoresist topcoat composition on the photoresist layer and performing a soft baking process to form a topcoat, exposing the topcoat and the photoresist layer to high-energy radiation, performing a post-exposure baking (PEB), and contacting the exposed and heat-treated topcoat and the photoresist layer with a developer to form a photoresist pattern.

The topcoat may have a thickness of about 1 nm to about 100 nm.

Another example embodiment of the present disclosure provides methods of forming patterns that includes applying a photoresist composition on a substrate and performing a soft baking process to form a photoresist layer, exposing the photoresist layer to high-energy radiation, performing a post-exposure baking (PEB), and contacting the exposed and heat-treated photoresist layer with a developer to form a photoresist pattern, wherein the photoresist composition may include a photosensitive polymer, a photoacid generator (PAG), the aforementioned photoresist topcoat composition, and a solvent.

An example embodiment of a photoresist topcoat composition may be included in an amount of about 1 part by weight to about 20 parts by weight based on 100 parts by weight of the photosensitive polymer.

An example embodiment of a photoresist topcoat composition according to the present disclosure may maintain or slightly increases an exposure dose of EUV resist while contact hole (C/H: contact hole), LCDU, IPU (in-point uniformity), LER/LWR and CD (critical dimension) distribution of L/S pattern, and IPU of pillar patterns may be greatly improved to increase a yield of products. Accordingly, the photoresist topcoat composition according to example embodiments or patterns prepared therefrom may be used for forming a fine pattern of a photoresist using a high-energy light source such as EUV.

### BRIEF DESCRIPTION OF THE DRAWINGS

FIG. 1 is a schematic view showing steps in a pattern forming method using a photoresist topcoat composition according to an example embodiment.

FIG. 2 is a schematic view showing steps in a method of forming patterns using a photoresist topcoat composition according to another example embodiment.

FIG. 3 is a schematic view showing a conventional method of forming patterns using a photoresist composition.

FIG. 4 is a graph showing the results of observing C/H IPU according to the resist thickness.

FIG. 5 is a result showing the LWR result of the L/S pattern according to the resist thickness.

FIG. 6 is a schematic view showing the occurrence of DOF (depth of focus) degradation and the resulting CD change in high-NA EUV equipment.

### DETAILED DESCRIPTION

The present disclosure will be described more fully hereinafter with reference to the accompanying drawings, in which example embodiments are shown. As those skilled in the art would realize, the described example embodiments may be modified in various different ways, all without departing from the spirit or scope of the present disclosure.

The drawings and description are to be regarded as illustrative in nature and not restrictive. Like reference numerals designate like elements throughout the specification.

The size and thickness of each constituent element as shown in the drawings are shown for better understanding and ease of description, and this disclosure is not necessarily limited to as shown. In the drawings, the thickness of layers, films, panels, regions, etc., are exaggerated for clarity. In the drawings, the thickness of a part of layers or regions, etc., is exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

In addition, unless explicitly described to the contrary, the word “comprise,” and variations such as “comprises” or “comprising”, will be understood to imply the inclusion of stated elements but not the exclusion of any other elements.

As used herein, when a definition is not otherwise provided, “substituted” refers to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

As used herein, when a definition is not otherwise provided, “hetero” refers to one including 1 to 10 heteroatoms selected from N, O, S, or P.

In addition, as used herein, an acrylic polymer refers to an acrylic polymer or a methacrylic polymer.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

As used herein, when a definition is not otherwise provided, “*” indicates a linking point of a structural unit or a compound moiety of a compound.

Hereinafter, photoresist topcoat compositions according to example embodiments will be described.

The present disclosure relates to photoresist topcoat compositions methods of forming photoresist patterns using such a topcoats which may increase the thickness of the PR during the fine pattern formation process of photolithography using high-energy rays such as EUV (extreme ultraviolet; wavelength 13.5 nm) to improve a contact hole (C/H: contact hole), LCDU, IPU (in-point uniformity), LER/LWR and CD (critical dimension) distribution of L/S patterns, IPU of pillar patterns, and resist pattern collapse.

A photoresist topcoat composition according to example embodiments may include a polymer including at least one or a combination of the first structural units represented by Chemical Formula 1, Chemical Formula 2, a thermal acid generator (TAG), and a solvent.

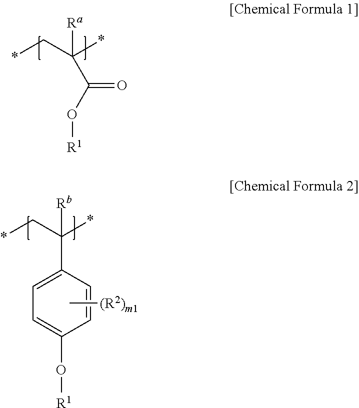

In Chemical Formula 1 and Chemical Formula 2,
R^{a} and R^{b} may each independently be hydrogen or a methyl group,
R¹ may be an acid functional group or an acid generating group, and
m1 is an integer from 1 to 4.

The photoresist topcoat composition according to an example embodiment may be applied on the photoresist layer to increase the resist thickness, thereby increasing a contact hole (C/H), LCDU, IPU (in-point uniformity), LER/LWR and CD (critical dimension) distribution of L/S patterns, and IPU of the pillar patterns.

On the other hand, as described above, the increase in resist thickness may improve distribution, but the residue on the PR bottom may not be well removed, causing scum and forming a contact hole not-open defect, and thus causing product yield to decrease.

In addition, if a PR thickness of 40 nm or more is used in a high-NA (for example, 0.55NA) exposure machine using a conventional process, DOF (depth of focus) may be reduced. Exposure performed in a defocused manner, may result in C/H IPU deterioration due to image quality deterioration.

However, photoresist topcoat compositions according to example embodiments may be removed in the developing process and develop the same PR thickness as the thickness without the topcoat, the problem of causing a contact hole not-open defect may be solved. During exposure, best focus may be applied to the lower portion of the photoresist layer, an area where the PR pattern remains maintains image quality. Since the upper portion of the PR, where image quality is deteriorated due to defocus, corresponds to the topcoat according to the present disclosure, it is removed during the developing process. Thus a photoresist topcoat composition according to example embodiments may be able to control the C/H IPU deterioration problem caused by defocus.

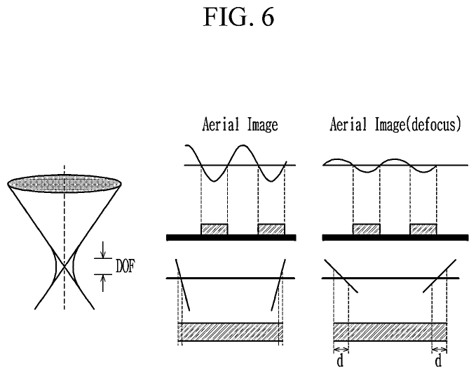

In this regard, FIG. 6 is a schematic view showing DOF (depth of focus) deterioration and resulting in CD change during exposure in a high-NA EUV exposure machine.

FIG. 6 shows DOF (depth of focus) deterioration and resulting CD change during exposure in a High-NA EUV exposure machine compared to exposure in a low-NA (e.g., 0.33NA) exposure machine, and image deterioration may occur due to defocus in the changed CD portion.

A photoresist topcoat composition according to an example embodiment includes a polymer including a first structural unit including an acid functional group or an acid generating group. In the exposure process, more secondary electrons can be generated, and thus the sensitivity of the lower photoresist layer may be improved, so that a photoresist pattern with uniform distribution may be obtained.

In addition, the positive tone chemically amplified photoresist layer may be deprotected by the acid generated in the topcoat composition, so that the acid generated during exposure removes an upper layer of the photoresist layer having an irregular line width.

For example, R¹ in Chemical Formula 1 may be a functional group derived from carboxylic acid, sulfonic acid, phosphoric acid, a hydrogen halide, or an L⁸SO₃⁻Q⁺ group,
L⁸ may be a substituted or unsubstituted C1 to C30 alkylene, a substituted or unsubstituted C6 to C30 arylene, or a combination thereof, and
Q⁺ may be an onium cation.

An example of the onium cation may be an ammonium ion, an iodonium ion, a sulfonium ion, or a combination thereof.

For example, the acid functional group or acid generator group may be a group derived from CF₃SO₃H, C₄F₉SO₃H, C₈F₁₇SO₃H, a 2-nitrobenzyl ester of sulfonic acid, imino sulfonate, 1-oxo-2-diazonaphthoquinone-4-sulfonate derivative, N-hydroxyl imide sulfonate, tri(methanesulfonyloxy)-benzene, O-nitrobenzyl ester, or the like.

An example embodiment of the first structural unit may include at least one or a combination of those listed in Group 1.

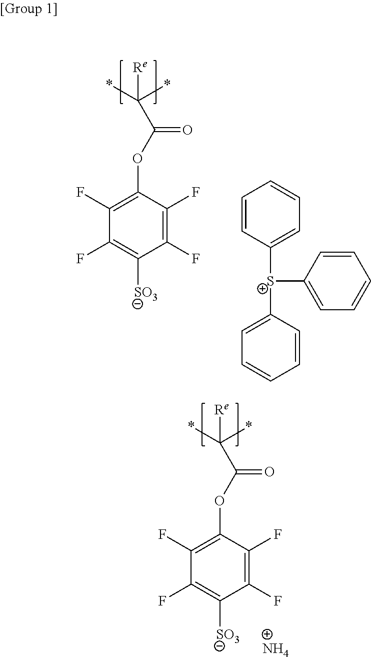

In Group 1,
R^{e} may be hydrogen or a methyl group.

The polymer may further include a second structural unit including at least one fluorine.

When a structural unit including fluorine is included, the surface energy may be lowered and a topcoat may be additionally formed with embedded self-assembly, so that exposure may be performed with increased topcoat thickness.

Without an additional topcoat forming process, the topcoat composition according to an embodiment may be added to the photoresist composition to realize the effect of forming the topcoat as a result.

An example embodiment of the second structural unit may include at least one or a combination of Chemical Formula 3 to Chemical Formula 5.

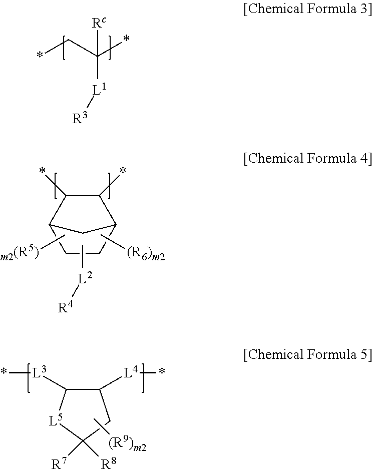

In Chemical Formula 3 to Chemical Formula 5,
R^{c} may be a hydrogen or a methyl group,
R⁵ to R⁸ may each independently be hydrogen, a fluoro group, a hydroxy group, a substituted or unsubstituted C1 to C4 alkyl, a substituted or unsubstituted C1 to C4 alkoxy group, or a substituted or unsubstituted C6 to C12 aryl group,
R³, R⁴, and R⁹ may each independently be a substituted or unsubstituted C1 to C30 alkyl group, a substituted or unsubstituted C1 to C30 alkoxy group, or a substituted or unsubstituted C6 to C30 aryl group,
L¹ to L⁶ may each independently be a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a divalent group selected from a substituted or unsubstituted C1 to C30 aliphatic ester or a combination thereof,
at least one of L¹ and R³ may include a fluoro group,
at least one of L² and R⁴ to R⁶ may include a fluoro group,
at least one of L³ to L⁵ and R⁷ to R⁹ may include a fluoro group, and
m2 is an integer of 1 or 2.

The second structural unit including fluorine may include a combination of two or more structural units of Chemical Formula 3 to Chemical Formula 5.

In Chemical Formula 3 to Chemical Formula 5, the fluoro (or fluorine)-containing group may further include a hydrophilic group such as a hydroxyl group or a carboxyl group.

For example, the fluoro (or fluorine)-containing group may be a C1 to C10 alkyl group substituted with a fluoro group (or fluorine group) or a C6 to C20 aryl group substituted with a fluoro group (or fluorine group), for example —CF₂OH, —CH₂CF₂OH, —CH₂CF₂CF₂OH, —CH(CF₃)OH, —CF₂CF(CF₃)OH, or —CCH₃(CF₃)OH, but is not limited thereto.

An example embodiment of the second structural unit may include at least one or a combination of those listed in Group 2.

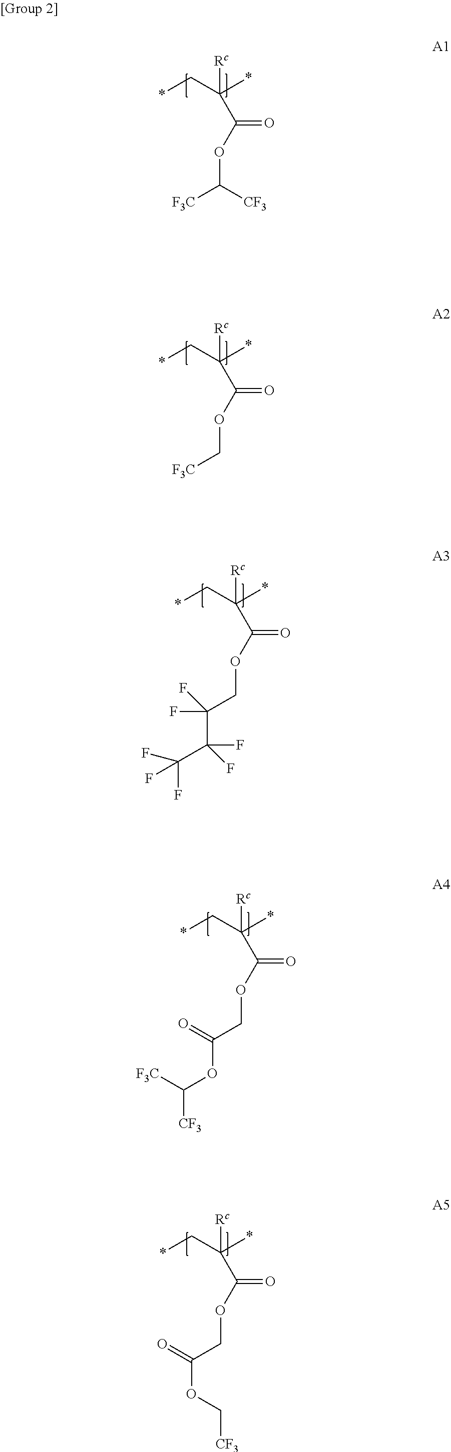

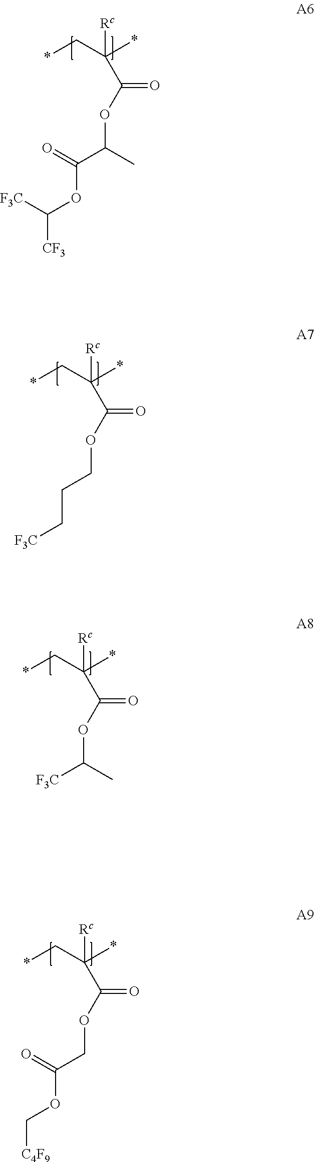

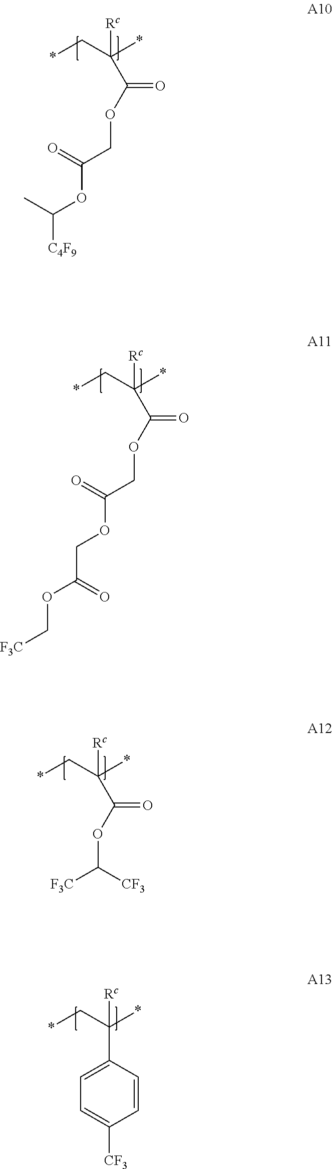

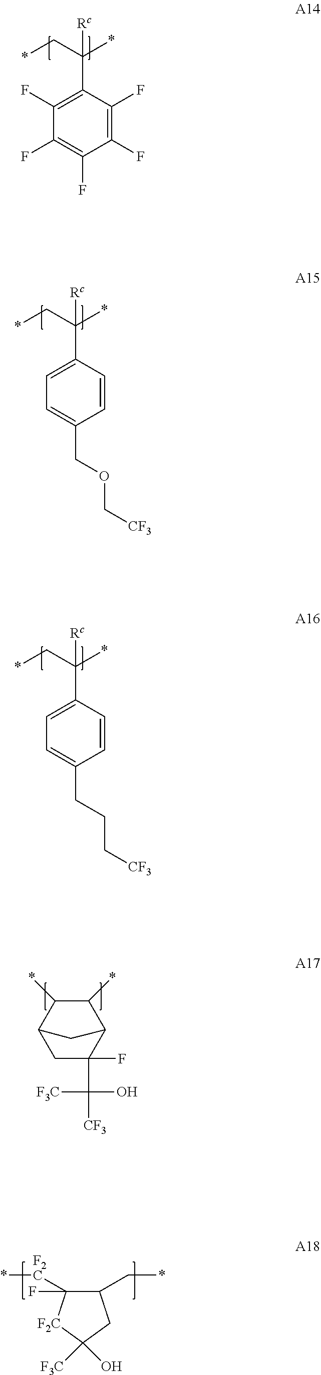

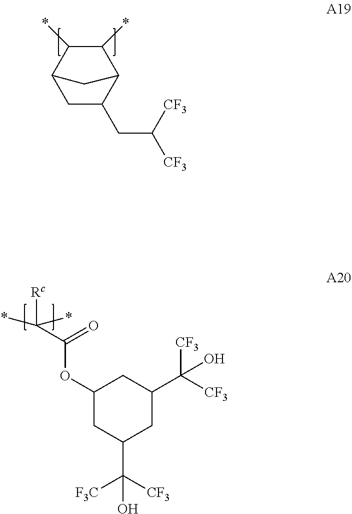

In Group 2,
R^{c} may be hydrogen or a methyl group.

The polymer may further include a third structural unit including at least one element selected from Sn, Sb, Te, I, Ti, Bi, Po, At, In, Hf, Ag, Au, Pt, Si, Al, or Ga.

As the third structural unit may be included, sensitivity may be further improved by increasing EUV absorption.

For example, the third structural unit may include at least one element selected from Sn, I, In, or Hf.

For example, the third structural unit may be represented by Chemical Formula 6.

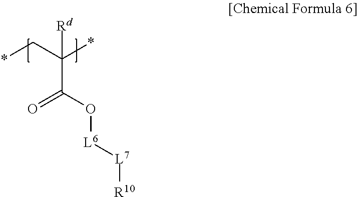

In Chemical Formula 6,
R^{d} may be hydrogen or a methyl group,
L⁶ and L⁷ may each independently be a divalent group selected from a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a substituted or unsubstituted C1 to C30 aliphatic ester, or a combination thereof,
R¹⁰ may be a substituted or unsubstituted C1 to C30 alkyl group, a substituted or unsubstituted C1 to C30 alkoxy group, or a substituted or unsubstituted C6 to C30 aryl group, and
At least one of L⁶, L⁷, and R¹⁰ may include at least one element selected from Sn, Sb, Te, I, Ti, Bi, Po, At, In, Hf, Ag, Au, Pt, Si, Al, or Ga.

In another example embodiment, the third structural unit may include at least one or a combination of those listed in Group 3.

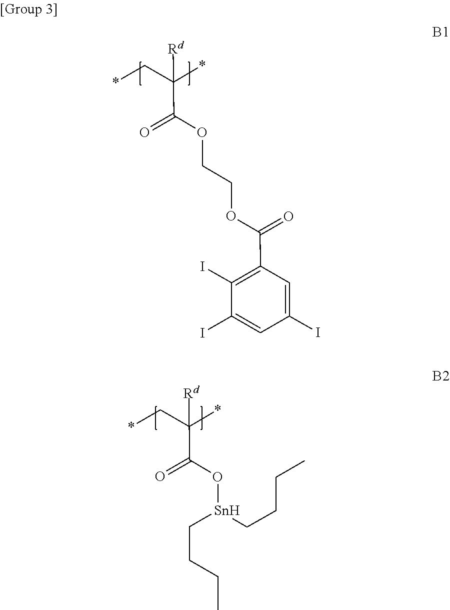

In Group 3,
R^{d} may be hydrogen or a methyl group.

Example embodiments of a polymer according to the disclosure herein may include a first structural unit, a first structural unit and a second structural unit, a first structural unit and a third structural unit, or a first structural unit, a second structural unit, and a third structural unit.

The thermal acid generator may be at least one of a nitrobenzyl tosylate such as 2-nitrobenzyl tosylate, 3-nitrobenzyl tosylate, 4-nitrobenzyl tosylate, 2,4-dinitrobenzyl tosylate, 2,6-dinitrobenzyl tosylate, 4-nitrobenzyl tosylate, and the like; benzenesulfonate such as 2-trifluoromethyl-6-nitrobenzyl 4-chlorobenzenesulfonate, 2-trifluoromethyl-6-nitrobenzyl 4-nitro benzenesulfonate, 2-trifluoromethyl-4-nitrobenzylbenzene sulfonate, 3-trifluoromethyl-4-nitrobenzylbenzene sulfonate, and the like; a phenol-based sulfonate ester such as phenyl, 4-methoxybenzenesulfonate, or the like; an alkyl ammonium salt of organic acid such as a triethylammonium salt of 10-camphorsulfonic acid; trifluoromethylbenzene sulfonic acid; perfluorobutane sulfonic acid; or an onium salt compound.

Examples of the onium salt compound may include ammonium triflate, ammonium perfluorobutane sulfonate (PFBuS), ammonium [4-adamantanecarboxyl-1,1,2,2-tetrafluorobutane sulfonate] (Ad-TFBS), ammonium Ad-TFBS [4-adamantanecarboxyl-1,1,2,2-tetrafluorobutane sulfonate], ammonium AdOH-TFBS [3-hydroxy-4-adamantanecarboxy-1,1,2,2-tetrafluorobutane sulfonate] (ammonium AdOH-TFBS [3-hydroxy-4-adamantanecarboxyl-1,1,2,2-tetrafluorobutane sulfonate]), ammonium Ad-DFMS [adamantanyl-methoxycarbonyl)-difluoromethanesulfonate], ammonium AdOH-DFMS[3-hydroxyadamantanyl-methoxycarbonyl)-difluoromethanesulfonate], ammonium DHC-TFBSS[4-di hydrocholate-1,1,2,2-tetrafluorobutanesulfonate] (ammonium DHC-TFBSS [4-dehydrocholate-1,1,2,2-tetrafluorobutane-sulfonate]), ammonium ODOT-DFMS [hexahydro-4,7-epoxyisobenzofuran-1(3H)-one, 6-(2,2′-difluoro-2-sulfonatoacetic acid ester)] (ammonium ODOT-DFMS [hexahydro-4,7-epoxyisobenzofuran-1(3H)-one,6-(2,2′-difluoro-2-sulfonatoacetic acid ester)]), or a combination thereof.

The thermal acid generator may be, for example, at least one ammonium perfluorobutane sulfonate, 3-nitrobenzyl tosylate, 4-nitrobenzyl tosylate, 2-trifluoromethyl-4-nitrobenzylbenzene sulfonate, or 3-trifluoromethyl-4-nitrobenzylbenzene sulfonate such as those listed in Group 4.

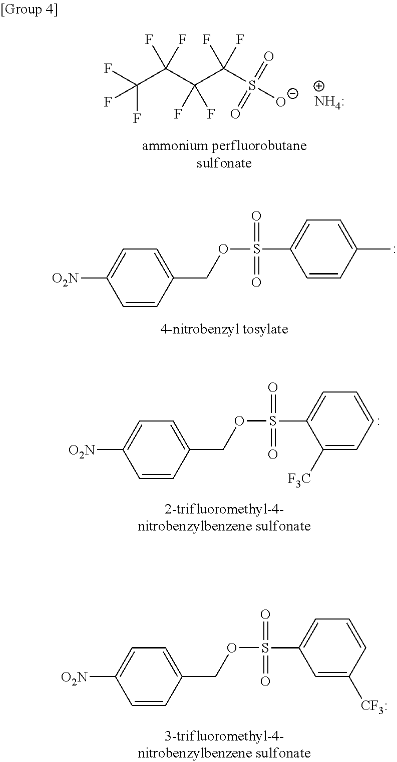

The polymer may have a weight average molecular weight (Mw) of about 10,000 to about 100,000, for example about 10,000 to about 80,000, for example about 10,000 to about 60,000, for example about 10,000 to about 50,000, or for example about 10,000 to about 20,000.

The photoresist composition according to one example embodiment may include the thermal acid generator in an amount of about 1 wt % to about 30 wt %, for example about 5 wt % to about 30 wt %, or for example about 10 wt % to about 30 wt %, based on solid contents. In particular, when the thermal acid generator is included in an amount of greater than or equal to about 10 wt %, thickness reduction control (recess) of a photoresist layer and the pattern thereof may be further improved during the development.

The thermal acid generator may diffuse acid from a coating film to the photoresist layer, the pattern, and the like to induce an appropriate top-loss of the photoresist layer. When the top-loss is induced by using strong acid, etc., there may be a problem of equipment corrosion, but when the top-loss is induced by the thermal acid generator, equipment maintenance may be improved.

The organic solvent that may be used does not affect the photoresist layer and pattern during application and coating film formation, and may include, for example, at least one of MIBC (methyl isobutyl carbinol), ether, PGMEA (propylene glycol monomethyl ether acetate), PGME (propylene glycol monomethyl ether), EL (ethyl lactate), HBM (β-hydroxy β-methylbutyric acid), water, or 2-heptanone.

A surfactant may be further included to increase the uniformity of the coating film. The surfactant that may be used may be a water-soluble anionic surfactant, a cationic surfactant, or an amphoteric surfactant. For example, it may be an alkylbenzenesulfonate-based surfactant, a higher amine halide, a quaternary ammonium salt-based surfactant, an alkylpyridinium salt-based surfactant, an amino acid-based surfactant, a sulfonimide-based surfactant, or the like. A content of the surfactant may be about 0.01 parts by weight to about 2 parts by weight, desirably about 0.1 parts by weight to about 1 part by weight, based on 100 parts by weight of the total photoresist topcoat composition.

Meanwhile, according to another example embodiment, a method of forming patterns using the aforementioned photoresist topcoat compositions may be provided. For example, the manufactured pattern may be a photoresist pattern.

A method of forming patterns according to an example embodiment may include applying a photoresist composition on a substrate and performing a soft baking process to form a photoresist layer, applying the aforementioned photoresist topcoat composition on the photoresist layer and performing a soft baking process to form a topcoat, exposing the topcoat and the photoresist layer to high-energy radiation, performing a post-exposure baking (PEB), and contacting the exposed and heat-treated topcoat and the photoresist layer with a developer to form a photoresist pattern.

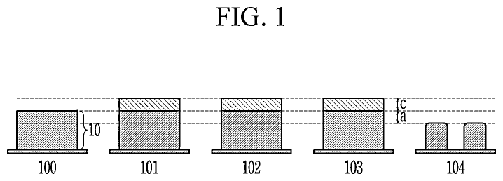

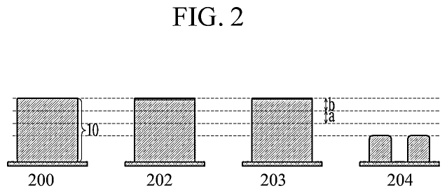

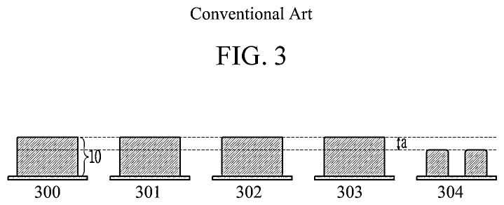

Hereinafter methods of forming patterns using the aforementioned photoresist topcoat composition according to example embodiments will be described with reference to FIGS. 1 to 3. FIGS. 1 and 2 are schematic views showing a method of forming patterns using a photoresist topcoat composition according example embodiments of the inventive concepts. FIG. 3 is a schematic view showing a method of forming patterns using a photoresist composition.

Referring to FIG. 1, an object to be etched is prepared. The object to be etched may be a thin film disposed on a semiconductor substrate. Hereinafter, the object to be etched will be described as limited to the thin film. In order to remove contaminants, etc. remaining on the thin film, the surface of the thin film may be washed. The thin film may be for example a silicon nitride film, a polysilicon film, or a silicon oxide film.

On the thin film, a photoresist composition may be coated and then soft-baked to form a photoresist layer 10 as depicted in operation 100. On the photoresist layer 10, the aforementioned photoresist topcoat composition may be coated and then soft-baked to form a topcoat c as may be depicted in operation 101.

The soft baking may be performed at about 80 ° C. to about 160 ° C. for about 30 seconds to about 150 seconds.

The topcoat c and the photoresist layer 10 may be exposed to high energy rays as depicted in operation 102.

For example, the high energy rays used for the exposure may be light with a high energy wavelength such as EUV (Extreme UltraViolet; wavelength 13.5 nm), E-Beam (electron beam), or the like.

The exposed region of the photoresist layer 10, that is, a region not covered with a patterned hardmask may be changed due to dissolubility in a developer, and thus has different solubility from that of the unexposed region of the photoresist layer.

Subsequently, a post-exposure baking (PEB) is performed as depicted in operation 103. After the exposure, the baking may be performed at about 80° C. to about 200° C. for about 30 seconds to about 150 seconds. Due to the baking after the exposure, the unexposed region of the photoresist layer may hardly be dissolved in the developer.

The exposed region of the photoresist layer 10 may be dissolved in the developer and removed, forming a photoresist pattern as depicted in operation 104.

Herein, a thickness-loss at the upper portion of the photoresist layer 10 with the topcoat c occurs.

A developer may be an alkali developer or a developer containing an organic solvent (hereinafter, organic developer).

The alkali developer may be in general a quaternary ammonium salt, which is represented by tetramethylammonium hydroxide, but in addition, an alkali aqueous solution such as an inorganic alkali, primary to tertiary amines, alcohol amines, cyclic amines, or the like.

In addition, the alkali developer may contain alcohols and/or a surfactant in an appropriate amount. An alkali concentration of the alkali developer may be, for example about 0.1 to about 20 mass %, and pH of the alkali developer may be, for example, about 10 to about 15.

The organic developer may be a developer containing at least one organic solvent selected from a ketone-based solvent, an ester-based solvent, an alcohol-based solvent, an amide-based solvent, an ether-based solvent, or a hydrocarbon-based solvent.

Examples of the ketone-based solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, or the like.

Examples of the ester-based solvent may include methyl acetate, butyl acetate, ethyl acetate, isopropyl acetate, pentyl acetate, isopentyl acetate, amyl acetate, propylene glycol monomethyl ether acetate, and ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, or the like.

Solvents that may be used as the alcohol-based solvent, include an amide-based solvent, an ether-based solvent, or a hydrocarbon-based solvent.

The aforementioned solvent may be prepared by mixing the solvents in plural or mixing with other solvents excluding the solvents or water. A total moisture content of the developer may be less than about 50 wt %, less than about 20 wt %, or less than about 10 wt %, or a substantially moisture-free developer.

The organic solvent of the organic developer may be about 50 wt % to about 100 wt %, about 80 wt % to about 100 wt %, about 90 wt % to about 100 wt %, or about 95 wt % to about 100 wt % based on the total amount of the organic developer.

The organic developer may contain an appropriate amount of surfactant.

A content of the surfactant may be usually about 0.001 wt % to about 5 wt %, about 0.005 wt % to about 2 wt %, or about 0.01 wt % to about 0.5 wt % based on the total amount of the developer.

The organic developer may include the aforementioned quencher.

The photoresist pattern may be applied as an etching mask to etch the exposed thin film. As a result, the thin film may be formed into a thin film pattern.

The etching of the thin film may be, for example, performed by dry etching using an etching gas. The etching gas may be, for example, CHF₃, CF₄, Cl₂, BCl₃, or a mixed gas thereof.

Referring to FIG. 2, on the thin film, a photoresist composition may be coated and then soft-baked, forming the photoresist layer 10 as depicted in operation 200. The photoresist layer 10 may be exposed to high energy rays as depicted in operation 202.

The post-exposure baking (PEB) may be performed as depicted in operation 203, and the developer may be used to dissolve and remove the photoresist layer 10 corresponding to the exposed region, forming a photoresist pattern as depicted in operation 204.

The PEB may be performed at the same temperature and at the same time as the soft baking described above.

An example embodiment of a photoresist composition may include a photosensitive polymer, a photoacid generator (PAG), the aforementioned photoresist topcoat composition, and a solvent. An example embodiment including a topcoat composition having a polymer including a structural unit containing fluorine, may have a lowered surface energy, an additional topcoat b may be formed with embedded self-assembly, and exposure may be performed in a state such that a thickness of the topcoat may be increased.

The additional topcoat b may implement the same effect as the aforementioned topcoat C.

Referring to FIG. 3, a photoresist composition may be soft-baked to form a photoresist layer 10 as depicted in operation 300. Neither a topcoat-forming process nor a topcoat formed by the topcoat composition included in the photoresist composition according to a conventional pattern-forming method, as depicted in operations 301 to 304. The photoresist composition may not be coated with a topcoat composition as depicted in operation 301. The photoresist layer 10 may be exposed to high energy rays as depicted in operation 302. The post-exposure baking (PEB) may be performed as depicted in operation 303, and the developer may be used to dissolve and remove the photoresist layer 10 corresponding to the exposed region, forming a photoresist pattern as depicted in operation 304. Accordingly, improved distribution effects do not result.

A photosensitive polymer may be used without limitation, and for example, an acrylic polymer may be used.

The semiconductor resist composition according to an example embodiment may include a photoacid generator (PAG), thereby improving the sensitivity and resolution characteristics of the semiconductor photoresist composition without deteriorating either the sensitivity or the resolution characteristics of the composition.

A photoacid generator (PAG) is a compound that generates an acid by irradiation with actinic rays or radiation.

The photoacid generator may be a compound that generates an organic acid by irradiation with actinic rays or radiation. For example, it may be a sulfonium salt compound, an iodonium salt compound, a diazonium salt compound, a phosphonium salt compound, an imide sulfonate compound, an oxime sulfonate compound, a diazodisulfone compound, a disulfone compound, or an o-nitrobenzyl sulfonate compound.

As the photoacid generator, a compound that generates an acid when irradiated with actinic rays or radiation may be appropriately selected and used alone or as a mixture thereof.

For example, the photoacid generator (PAG) may include a cationic compound represented by Chemical Formula 7, Chemical Formula 8, or Chemical Formula 9.

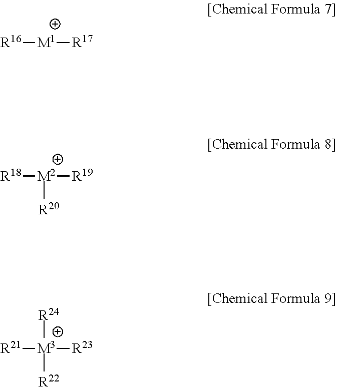

In Chemical Formula 7 to Chemical Formula 9,
M¹ may be F, CI, Br, or I,
M² may be O, S, Se, or Te,
M³ may be N, P, As, or Sb, and
R¹⁶ to R²⁴ may each independently be a substituted or unsubstituted C1 to C20 alkyl group, a substituted or unsubstituted C3 to C20 cycloalkyl group, a substituted or unsubstituted C2 to C20 aliphatic unsaturated organic group including at least one double bond or triple bond, a substituted or unsubstituted C6 to C30 aryl group, or a combination thereof.

More specifically, the photoacid generator (PAG) may include a cationic compound represented by Chemical Formula 10 or Chemical Formula 11.

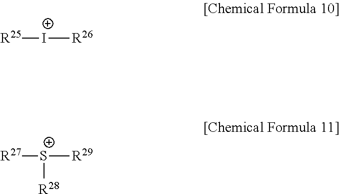

In Chemical Formula 10 and Chemical Formula 11,
R²⁵ to R²⁹ may each independently be a substituted or unsubstituted C1 to C20 alkyl group, a substituted or unsubstituted C3 to C20 cycloalkyl group, a substituted or unsubstituted C2 to C20 aliphatic unsaturated organic group including at least one double bond or triple bond, a substituted or unsubstituted C6 to C30 aryl group, or a combination thereof.

The semiconductor photoresist composition according to an example embodiment may include the aforementioned photoacid generator (PAG) in an amount of about 0.1 wt % to about 10 wt %, for example about 0.3 wt % to about 10 wt %, or for example about 0.5 wt % to about 10 wt %. When the photoacid generator (PAG) is included within the content ranges in the semiconductor photoresist composition, sensitivity and resolution characteristics may be improved without deteriorating either one of the sensitivity and resolution characteristics.

The solvent included in the semiconductor resist composition according to an example embodiment may be an organic solvent, and for example, an organic solvent such as an alkylene glycol monoalkyl ether carboxylate, an alkylene glycol monoalkyl ether, an alkyl lactate ester, an alkyl alkoxy propionate, a cyclic lactone (desirably having 4 to 10 carbon atoms), a monoketone compound having a ring (desirably having 4 to 10 carbon atoms), alkylene carbonate, alkyl alkoxyacetate, or alkyl pyruvate may be appropriately used. For example, a mixed solvent obtained by mixing a solvent having a hydroxyl group and a solvent having no hydroxyl group in the structures may be used.

The solvent may have a hydroxyl group; however, example embodiments are not so limited thereto. For example, the solvent may not have a hydroxyl group. Example compounds of solvents described above may be appropriately selected. Examples of the solvent having a hydroxyl group may include alkylene glycol monoalkyl ether, alkyl lactate, or the like, such as propylene glycol monomethyl ether (PGME), propylene glycol monoethyl ether (PGEE), methyl 2-hydroxyisobutyrate, ethyl lactate, or the like. Examples of solvents not having a hydroxyl group may include alkylene glycol monoalkyl ether acetate, alkyl alkoxy propionate, a monoketone compound which may have a ring, cyclic lactones, or alkyl acetate Additionally, propylene glycol monomethyl ether acetate (PGMEA), ethyl ethoxypropionate (specifically, ethyl 3-ethoxypropionate), 2-heptanone, γ-butyrolactone, cyclohexanone, cyclopentanone, 3-methoxybutyl acetate, or butyl acetate, and the like, and for example propylene glycol monomethyl ether acetate, γ-butyrolactone, ethyl ethoxypropionate, cyclohexanone, cyclopentanone, 2-heptanone, or the like may be used. Propylene carbonate etc. may be used as a solvent not having a hydroxyl group.

In other example embodiments, the solvent may include propylene glycol monomethyl ether acetate, and may be a single solvent of propylene glycol monomethyl ether acetate, or a mixture of two or more including propylene glycol monomethyl ether acetate, but is not limited thereto.

The solvent may be included in a balance amount in the semiconductor photoresist composition, and specifically in an amount of about 65 wt % to about 95 wt %, for example, about 70 wt % to about 95 wt %, or for example, about 75 wt % to about 95 wt %. When included within the corresponding content ranges, appropriate coating may be achieved.

In addition, the semiconductor resist composition according to an example embodiment may further include an additive according to circumstances. Examples of the additive may include a quencher, a surfactant, an acid increasing agent, a dye, a plasticizer, a photosensitizer, a light absorber, an alkali-soluble resin, a dissolution inhibitor, a dissolution promoter, or a combination thereof.

The quencher may trap acid generated from the photoacid generator, etc. during the exposure and thus suppress a reaction of an acid-decomposable resin in the unexposed region due to the excessively generated acid. For example, a basic compound, a basic compound of which basicity is reduced or lost by irradiation with actinic rays or radiation, an onium salt which is a relatively weak acid to the acid generator, a low-molecular compound having a nitrogen atom and a group removed by action of an acid, an onium salt compound having a nitrogen atom at a cation moiety or the like may be used as the acid diffusion control agent.

The quencher may be diphenyl (p-tolyl) amine, methyl diphenyl amine, triphenyl amine, phenylenediamine, naphthylamine, diaminonaphthalene, or a combination thereof.

The surfactant may include, for example, an alkylbenzenesulfonic acid salt, an alkylpyridinium salt, polyethylene glycol, a quaternary ammonium salt, or a combination thereof, but is not limited thereto.

An amount of the additive may be easily adjusted according to desired physical properties. Additionally, in some example embodiments, the additive may be omitted.

In addition, the composition for a semiconductor resist may further use a silane coupling agent to enhance adherence with a substrate of the semiconductor resist composition and improve adhesion to a substrate. For example, a silane coupling agent may include, for example, a carbon-carbon unsaturated bond-containing silane compound such as vinyltrimethoxysilane, vinyltriethoxysilane, vinyl trichlorosilane, and vinyltris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldi ethoxysilane; trimethoxy[3-(phenylamino)propyl]silane, or the like, but is not limited thereto.

An example embodiment of a semiconductor photoresist composition may be used for deep curing. Such an example embodiment may improve adhesion of a resist film to a substrate and improve sensitivity of a resist pattern formed by using the same, thereby improving the LWR of the resist pattern.

Hereinafter, the present invention will be described in more detail through examples related to the preparation of the aforementioned photoresist topcoat composition. However, the present invention is not technically limited by the following examples.

### EXAMPLES

### (Preparation of Topcoat Composition)

### Examples 1 to 4

Each topcoat composition was prepared by using a first structural unit, a second structural unit, and a third structural unit to synthesize a polymer in a mole ratio of 30:50:20, dissolving the polymer and ammonium perfluorobutane sulfonate as a thermal acid generator in a ratio of 50:50 parts by weight in an MIBC solvent, and filtering the solution through a TEFLON (tetrafluoroethylene) filter with a pore size of 0.45 μm. The polymer had a specific composition shown in Table 1.

### First Structural Unit

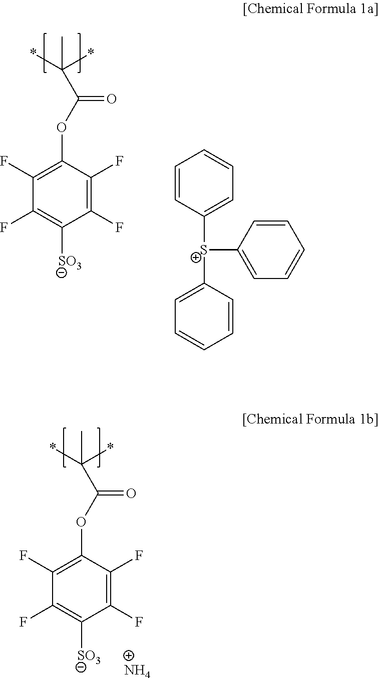

### Second Structural Unit

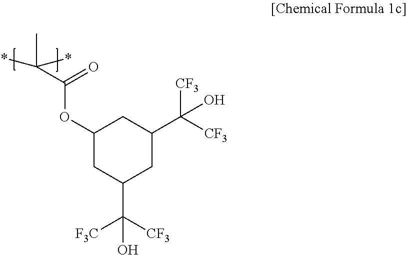

### Third Structural Unit

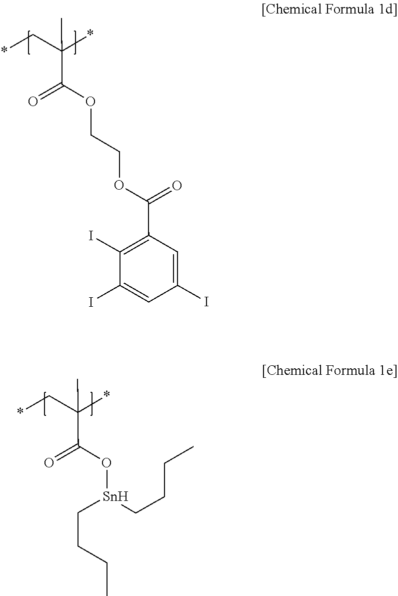

### Comparative Example 1

A topcoat composition was prepared in the same manner as in Examples 1 to 4, except that a polymer consisting of the second structural unit represented by Chemical Formula 1c alone was used.

TABLE 1

| | First | Second | Third |
|---|---|---|---|
| Polymer | structural unit | structural unit | structural unit |
| Example 1 | Chemical | Chemical | Chemical |
| | Formula 1a | Formula 1c | Formula 1d |
| Example 2 | Chemical | Chemical | Chemical |
| | Formula 1a | Formula 1c | Formula 1e |
| Example 3 | Chemical | Chemical | Chemical |
| | Formula 1b | Formula 1c | Formula 1d |
| Example 4 | Chemical | Chemical | Chemical |
| | Formula 1b | Formula 1c | Formula 1e |
| Comparative | — | Chemical | — |
| Example 1 | | Formula 1c | |

### (Preparation of Photoresist Composition Including Topcoat Composition)

### Examples 5 to 8

Each photoresist composition was prepared by dissolving 100 parts by weight of a methacrylate polymer having a protecting group, 10 parts by weight of each solid according to Examples 1 to 4, 20 parts by weight of PAG-1 (sulfonium-based, Sigma-Aldrich Corp.), and 8 parts by weight of a quencher in a PGMEA solvent and filtering each solution through a 0.1 μm PTFE (polytetrafluoroethylene) syringe filter.

### Evaluation 1: Measurement of Distribution According to Resist Thickness

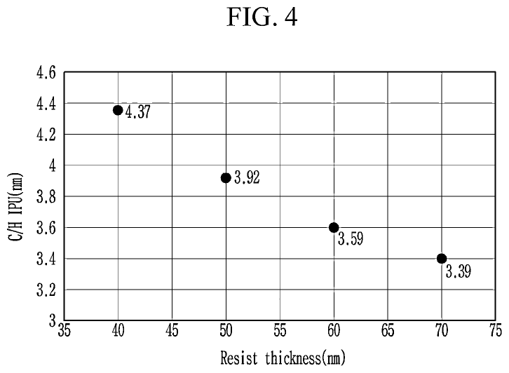

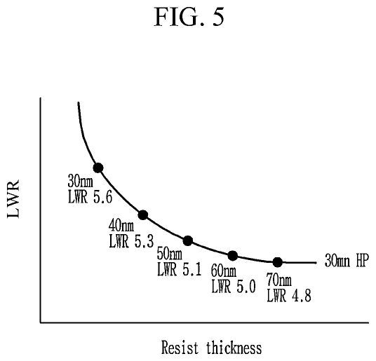

LER (Line and Edge Roughness) was examined using a critical dimension-scanning microscope (CD-SEM) for observing a pattern line width (critical dimension) of a wafer, and a step difference (center height−edge height) with reference to a height between edge and center of a C/H (contact hole) pattern was examined using a field emission-scanning-microscope (FE-SEM) for observing a pattern cross-section (cross profile). These measurement results are shown in Table 2 and FIGS. 4 and 5.

TABLE 2

| Resist | Exposure dose | | |
|---|---|---|---|
| thickness (Å) | (mJ/cm²) | CD @ 45P | IPU |
| 400 | 35 | 25.05 | 4.37 |
| 500 | 37.4 | 25.20 | 3.92 |
| 600 | 38.9 | 25.15 | 3.59 |
| 700 | 39.4 | 25.38 | 3.39 |

FIG. 4 is a graph showing the results of observing C/H IPU according to the resist thickness.

Referring to Table 2 and FIG. 4, as the resist thickness increased, C/H IPU decreased, which indicates that distribution was improved.

FIG. 5 is a result showing the LWR result of the L/S pattern according to the resist thickness.

Referring to FIG. 5, as the resist thickness increased, LWR of L/S patterns decreased, which indicates that distribution was improved.

While this example embodiments have been described herein, it is to be understood that the inventive concept is not limited to the disclosed embodiments, but, on the contrary, is intended to cover various modifications and equivalent arrangements included within the spirit and scope of the appended claims.

What is claimed is:

1. A photoresist topcoat composition, comprising:
a polymer including at least one of the first structural units represented by Chemical Formula 1 or Chemical Formula 2;
a thermal acid generator (TAG); and
a solvent: 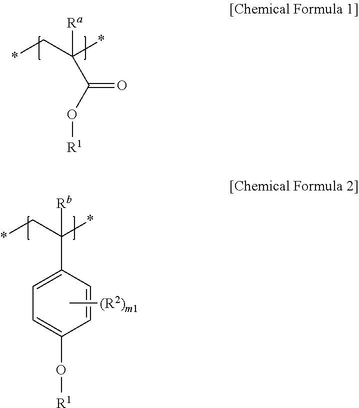
wherein, in Chemical Formula 1 and Chemical Formula 2,
R^{a} and R^{b} are each independently hydrogen or a methyl group,
R¹ is an acid functional group or an acid generating group, and
m1 is an integer from 1 to 4.

2. The photoresist topcoat composition of claim 1, wherein
R¹ is a functional group derived from carboxylic acid, sulfonic acid, phosphoric acid, a hydrogen halide, or an L⁸SO₃⁻Q⁺ group,
L⁸ is a substituted or unsubstituted C1 to C30 alkylene, a substituted or unsubstituted C6 to C30 arylene, or a combination thereof, and
Q⁺ is an onium cation.

3. The photoresist topcoat composition of claim 2, wherein
the onium cation is an ammonium ion, an iodonium ion, a sulfonium ion, or a combination thereof.

4. The photoresist topcoat composition of claim 1, wherein
the polymer further includes a second structural unit including at least one fluorine.

5. The photoresist topcoat composition of claim 4, wherein
the second structural unit is represented by any one of Chemical Formula 3 to Chemical Formula 5: 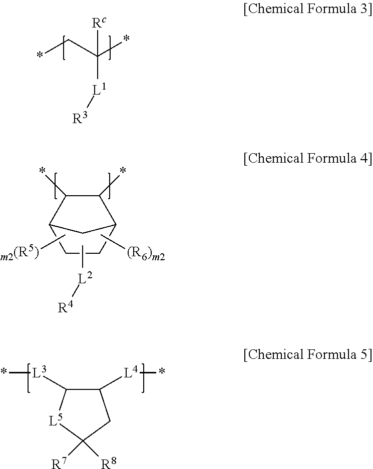
wherein, in Chemical Formula 3 to Chemical Formula 5,
R^{c} is hydrogen or a methyl group,
R⁵ to R⁸ are each independently hydrogen, a fluoro group, a hydroxy group, a substituted or unsubstituted C1 to C4 alkyl, a substituted or unsubstituted C1 to C4 alkoxy group, or a substituted or unsubstituted C6 to C12 aryl group,
R³, R⁴, and R⁹ are each independently a substituted or unsubstituted C1 to C30 alkyl group, a substituted or unsubstituted C1 to C30 alkoxy group, or a substituted or unsubstituted C6 to C30 aryl group,
L¹ to L⁶ are each independently a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a divalent group selected from a substituted or unsubstituted C1 to C30 aliphatic ester, or a combination thereof,
at least one of L¹ and R³ includes a fluoro group,
at least one of L² and R⁴ to R⁶ includes a fluoro group,
at least one of L³ to L⁵ and R⁷ to R⁹ includes a fluoro group, and
m2 is an integer of 1 or 2.

6. The photoresist topcoat composition of claim 4, wherein
the second structural unit is selected from those listed in Group 2: 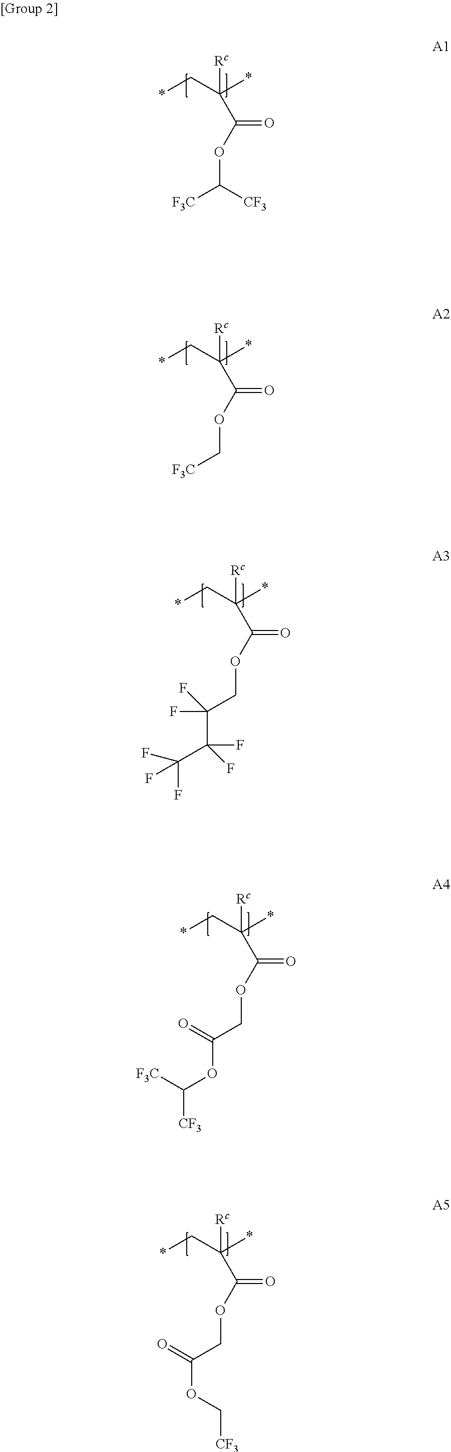 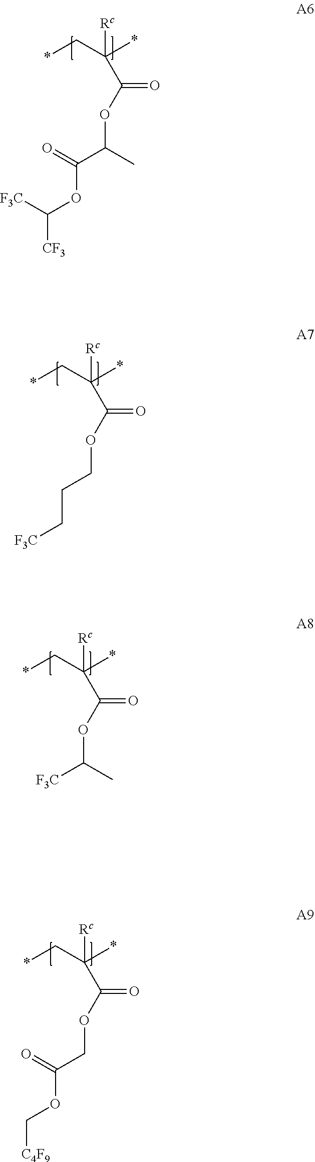 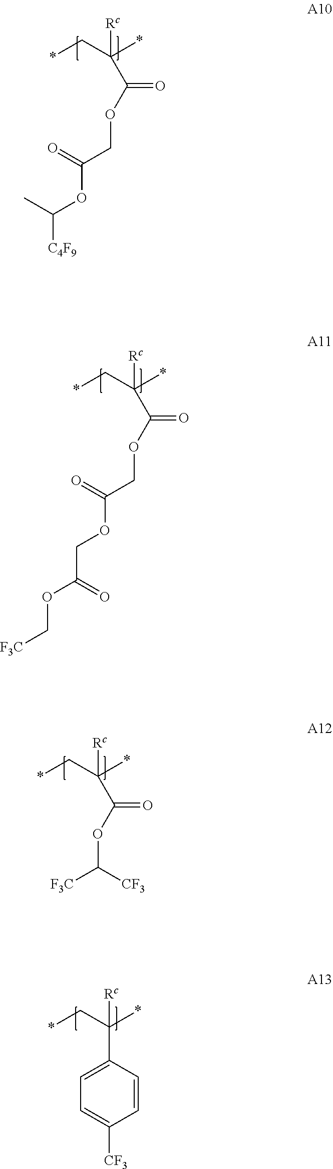 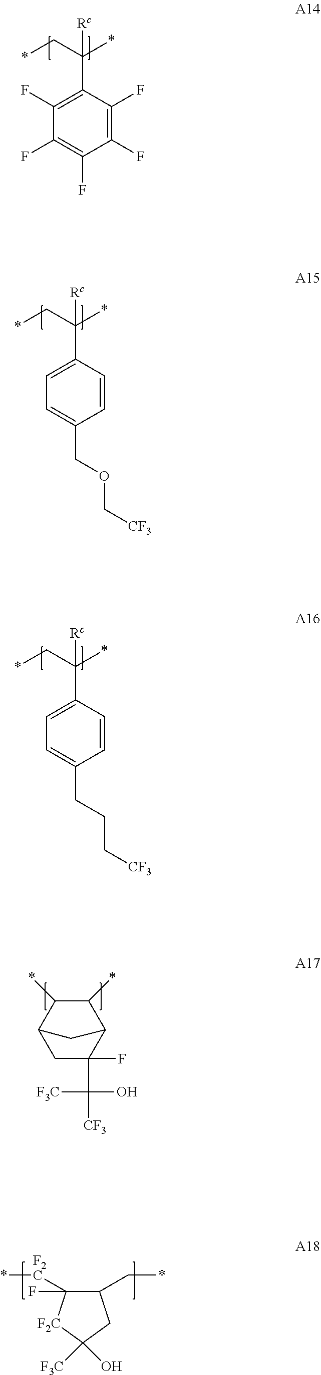 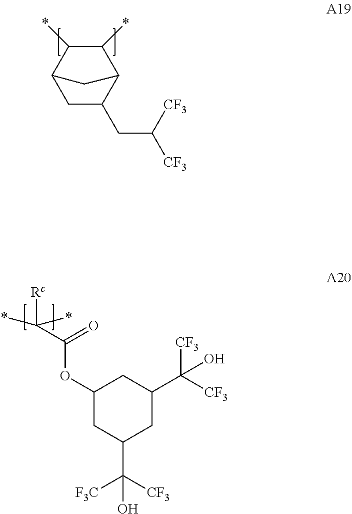
wherein, in Group 2,
R^{c} is hydrogen or a methyl group.

7. The photoresist topcoat composition of claim 4, wherein
the polymer further includes a third structural unit including at least one element selected from Sn, Sb, Te, I, Ti, Bi, Po, At, In, Hf, Ag, Au, Pt, Si, Al, or Ga.

8. The photoresist topcoat composition
of claim 7, wherein
the third structural unit further includes at least one element selected from Sn, I, In, or Hf.

9. The photoresist topcoat composition of claim 7, wherein
the third structural unit is represented by Chemical Formula 6: 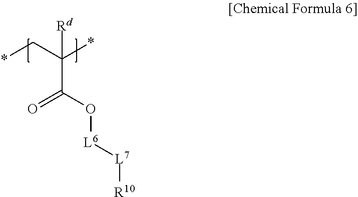
wherein, in Chemical Formula 6,
R^{d} is hydrogen or a methyl group,
L⁶ and L⁷ are each independently a divalent group selected from a single bond, a substituted or unsubstituted C1 to C30 alkylene, a substituted or unsubstituted C1 to C30 alkyleneoxy, a substituted or unsubstituted C1 to C30 oxyalkylene, a substituted or unsubstituted C1 to C30 carbonylalkylene, a substituted or unsubstituted C1 to C30 alkylenecarbonyl, a substituted or unsubstituted C1 to C30 carbonyloxyalkylene, a substituted or unsubstituted C1 to C30 carbonyloxyalkyleneoxy, a substituted or unsubstituted C1 to C30 alkylenecarbonyl, a substituted or unsubstituted C6 to C30 arylene, a substituted or unsubstituted C6 to C30 aryleneoxy, a substituted or unsubstituted C6 to C30 oxyarylene, a substituted or unsubstituted C6 to C30 carbonylarylene, a substituted or unsubstituted C6 to C30 carbonyloxyarylene, a substituted or unsubstituted C6 to C30 arylenecarbonyloxy, carbonyl, oxy, oxycarbonyl, carbonyloxy, a substituted or unsubstituted C1 to C30 aliphatic ester, or a combination thereof,
R¹⁰ is a substituted or unsubstituted C1 to C30 alkyl group, a substituted or unsubstituted C1 to C30 alkoxy group, or a substituted or unsubstituted C6 to C30 aryl group, and
at least one of L⁶, L⁷, and R¹⁰ includes at least one element selected from Sn, Sb, Te, I, Ti, Bi, Po, At, In, Hf, Ag, Au, Pt, Si, Al, or Ga.

10. The photoresist topcoat composition of claim 7, wherein
the third structural unit is selected from those listed in Group 3: 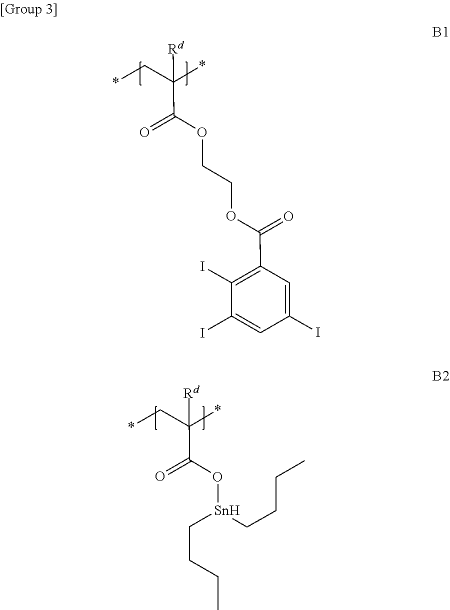
wherein, in Group 3,
R^{d} is hydrogen or a methyl group.

11. The photoresist topcoat composition of claim 1, wherein
the thermal acid generator is at least one of nitrobenzyl tosylate; benzenesulfonate; a phenol-based sulfonate ester; an alkyl ammonium salt of an organic acid; trifluoromethylbenzene sulfonic acid; perfluorobutane sulfonic acid; or an onium salt compound.

12. The photoresist topcoat composition of claim 1, wherein
a weight average molecular weight (Mw) of the polymer is about 10,000 to about 100,000.

13. The photoresist topcoat composition of claim 1, wherein
the thermal acid generator is included in an amount of about 1 weight percent to about 30 weight percent based on the total solid content of the composition.

14. The photoresist topcoat composition of claim 1, wherein
the thermal acid generator is included in an amount of about 10 weight percent to about 30 weight percent based on the total solid content of the composition.

15. The photoresist topcoat composition of claim 1, wherein
the organic solvent is at least one of MIBC (methyl isobutyl carbinol), ether, PGMEA (propylene glycol monomethyl ether acetate), PGME (propylene glycol monomethyl ether), EL (ethyl lactate), HBM (β-hydroxy β-methylbutyric acid), water, or 2-heptanone.

16. A method of forming patterns, comprising
applying a photoresist composition on a substrate and performing a soft baking process to form a photoresist layer,
applying the photoresist topcoat composition of claim 1 on the photoresist layer and performing a soft baking process to form a topcoat,
exposing the topcoat and the photoresist layer to high-energy radiation,
performing a post-exposure baking (PEB), and
contacting the exposed and heat-treated topcoat and the photoresist layer with a developer to form a photoresist pattern.

17. The method of claim 16, wherein
the topcoat has a thickness of about 1 nm to about 100 nm.

18. A method of forming patterns, comprising
applying a photoresist composition on a substrate and performing a soft baking process to form a photoresist layer,
exposing the photoresist layer to high-energy radiation,
performing a post-exposure baking (PEB), and
contacting the exposed and heat-treated photoresist layer with a developer to form a photoresist pattern,
wherein the photoresist composition includes a photosensitive polymer, a photoacid generator (PAG), the photoresist topcoat composition of claim 4, and a solvent.

19. The method of claim 18, wherein
the photoresist topcoat composition is included in an amount of about 1 part by weight to about 20 parts by weight based on 100 parts by weight of the photosensitive polymer.

20. The method of claim 18, wherein
the photoresist composition further includes a quencher, a surfactant, an acid increasing agent, a dye, a plasticizer, a photosensitizer, a light absorber, an alkali-soluble resin, a dissolution inhibitor, a dissolution promoter, or a combination thereof.
